(19) United States
(12) Patent Application Publication
(10) Pub. No.: US 2006/0050527 A1
(43) Pub. Date: Mar. 9, 2006

(54) Light engine mounting

(75) Inventors: Michael Joseph Rehberger, Kinnelon, NJ (US); Krzysztof Sosniak, Wallington, NJ (US); Robert Martin Sagebiel, Groveville, NJ (US)

Correspondence Address: OSTROLENK FABER GERB & SOFFEN, 1180 AVENUE OF THE AMERICAS, NEW YORK, NY, 100368403, US

(73) Assignee: CLM INNOVATIVE TECHNOLOGIES, INC.

(21) Appl. No.: 11/221,685

(22) Filed: Sep. 8, 2005

Related U.S. Application Data
(60) Provisional application No. 60/608,497, filed on Sep. 9, 2004.

(51) Int. Cl. H01L 33/00

(52) U.S. Cl. 362/555

(57) ABSTRACT

A light engine having a housing for containing a light emitting diode, the housing having a distal side and a shank projecting from the distal side. The shank is passed through a panel to be on the distal side of the panel while the housing is on the proximal side. A first shank seal outside the shank seals the exterior of the shank at the distal side of the panel. A second light guide seal at a cap at the distal end of the shank seals the cap and the shank around a light guide rod extending into the cap.

### CROSS-REFERENCE TO RELATED APPLICATION

This application claims the benefit of the filing date of U.S. Provisional Patent Application No. 60/608,497 filed Sep. 9, 2004, the disclosure of which is hereby incorporated herein by reference.

### BACKGROUND OF THE INVENTION

The present invention concerns a light engine which houses one or more LEDs (light emitting diodes) and a mounting connecting the housing, in which the LED(s) are housed, to a conventional cable or rod light guide, which is either flexible or rigid. In particular, the invention concerns the design of the light engine mounting which enables it to be mounted such that water or other liquid will not pass the mounting and particularly will not move to the LED housing from the environment surrounding the cable or light guide.

A light engine supplies light from a light source, here LEDs, to a conventional cable or rod type light guide, which transmits light incident upon the proximal end of the light guide to the distal end thereof to illuminate an object.

The environments of uses or applications of light engines are very diverse. Sometimes a light engine associated with a cable or rod light guide is used in a humid, damp or wet environment where the ambient environment might damage the LEDs, the supports thereof, the connections thereto or the housing of the LEDs while the light guide would be unaffected. The invention concerns a mounting of the light engine housing which prevents the passage of moisture, humidity, or liquid which is most often water, through or along the light engine, typically from the light guide side to the LED housing side, but also vice versa. Mounting a light engine to a wall or panel through which the light engine may be passed is known. According to the invention here, the light engine includes fixtures for attaching the housing of the light engine to a wall or panel through which the light engine may be passed.

### SUMMARY OF THE INVENTION

According to the invention, the light engine includes O-rings or rubber washers at two locations, sealing the light guide in the end of the housing of the light engine and sealing the housing at the panel or wall, which makes the mounting of the light engine water, moisture and humidity tight and prevents water, liquid or moisture passing through or along the light engine, from the rod side to the LED side, or vice versa.

In the invention, one or more LEDs is mounted inside a tubular housing. The LEDs are typically on a heat sink block, although alternate mounting techniques are available. Leads pass from the LEDs out of the housing typically through the block. The mountable end of the housing has a hollow shank that is passed through a wall, panel or the like to which the housing is to be mounted. There is a light transmitting optical path from the LEDs into the hollow of the shank. The shank is open or hollow and holds the proximal end region of the light guide to receive light from the LEDs. The housing abuts at the proximal side of the wall, panel, or the like. Then a clamping element, e.g., a hex nut disposed on the preferably threaded shank, which securely holds the shank at its side of the wall or panel, is tightened against the opposite distal side of the wall, panel, or the like, and secures the housing at the wall, panel or the like. There is a first seal between the clamping element, e.g., the hex nut, that secures the shank on the one and the light guide side or distal side of the wall, panel, or the like on the other hand. The seal may have the form of an O-ring or a rubber washer.

The proximal end region of the light guide is held securely in the projecting shank. An additional clamping element may be provided over the distal end of the shank to hold the light guide securely at the end of the shank. A second seal is provided between the additional clamping element and the shank to seal against leakage between the outside of the light guide and the inside of the shank. The second seal may have the form of an additional O-ring or a rubber washer.

It is an object of the invention to mount a light engine to a wall, panel, or the like mounting in a manner which protects against the passage of moisture, liquid or water between the LED housing on one side of the mounting and the light guide on the other side of the mounting.

Another object of the invention is to securely mount the light engine against the possible effects of the environment in which the light engine is used.

Another object is to transmit light from LEDs into the end of a light guide.

Other features and advantages of the present invention will become apparent from the following description of the invention which refers to the accompanying drawings.

### BRIEF DESCRIPTION OF THE DRAWINGS

FIG. 1 is a side view of a light engine and a fragment of the light guide according to the invention;

FIG. 2 is a longitudinal cross-sectional view thereof;

FIG. 3 is a detail of a sealing region for the light guide; and

FIG. 4 is a perspective view of the light engine and of the fragment of the light guide.

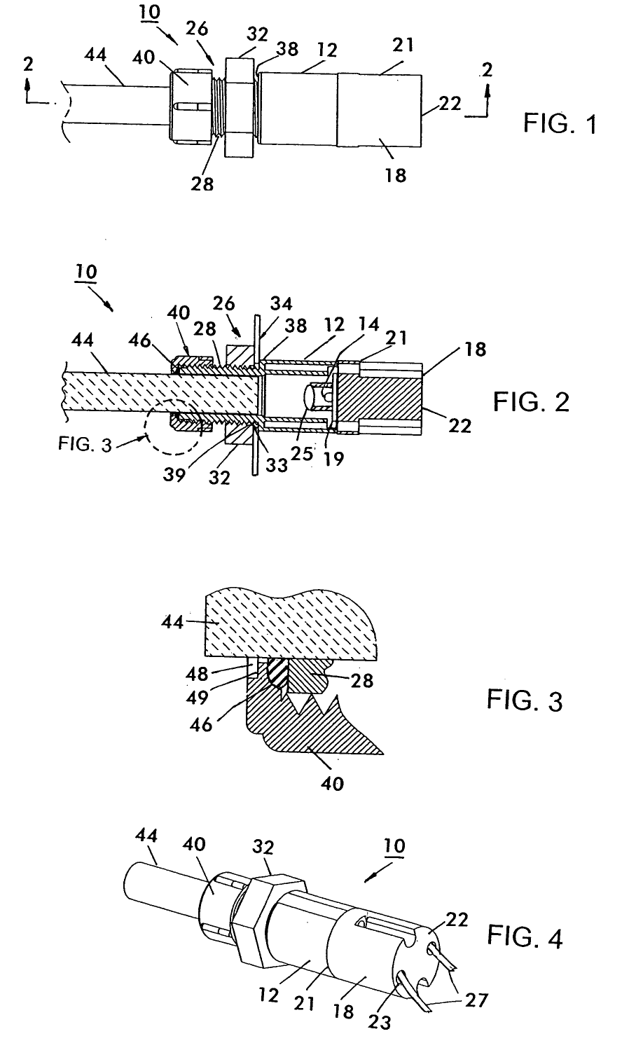

### DESCRIPTION OF A PREFERRED EMBODIMENT

A light engine 10 includes a tubular housing 12 which is optically open at the distal end thereof and may be covered there by an enclosing transparent layer in which at least one LED 14 is supported, e.g., by a mounting 16 for the LED.

One or more, without any limit theoretically, of the LEDs may be disposed inside the tubular housing 12 of the light engine, depending on the particular application, and the need for particular light intensity and/or choice of combinations of different colors of LEDs.

In one embodiment, the mounting is an aluminum heat sink block 18 supported at an end 21 of the housing 12. The LED 14 or a plurality of the LEDs are mounted and electrically connected to a respective printed circuit (PC) board 19. The PC board is attached to a heat sink block 18 by thermal adhesive between them. The block 18 does not completely fill the housing 12 from end to end. The LEDs are electrically connected from the PC board 19 by leads 21 passing through openings 23 in the end 22 of the heat sink block 18.

In a preferred embodiment, a lens 25 is disposed in the housing to focus the light from the LEDs on the proximal end of the below described light guide 44. The lens 25 is shown mounted on the PC board 19, but may be supported in or integrated into the housing in other ways.

In another embodiment, not shown, the LEDs are mounted in the housing but are not mounted on a heat sink block there.

An alternative design does not use a PC board. Instead, the heat sink is treated externally so as to be electrically isolated. Then the circuit for energizing the LEDs is printed on the heat sink. Then the heat sink and the LEDs are attached both electrically and mechanically to the heat sink. With this arrangement, a better thermal path may be achieved than with use of a PC board. Thermal adhesive, which may be provided to hold the heat sink, may here be unnecessary.

The other end region 26 of the housing 12 is enclosed in an externally screw threaded shank 28 which is narrower than the rest of the housing. A hexagonal periphery nut 32 is screwed onto the screw thread of the shank 28. The housing, and particularly the narrowed, screw threaded shank 28 thereof, is passed through an essentially correspondingly sized opening 33 in a wall, panel, or the like 34 to which the light engine is to be mounted. For convenience, the word panel may be used herein to cover the various alternatives. The hex nut 32 is applied to the threaded shank 28 and is tightened against the distal side of the panel 34 to clamp the outwardly facing, wider distal end 38 of the base of the housing 12 to the proximal side of the panel 34.

A first O-ring seal 39 inside the hex nut is squeezed against the distal side of the panel 34 at the thread and provides a water tight seal past the hex nut to the other side of the panel 34.

Outward of the hex nut along the shank 28, there is a second separate, finger tightenable compression cap 40, illustrated as a knurled nut, which also is threaded on the projecting screw threaded shank 28 of the LED housing and is tightened down toward the distal side of the hex nut 32. The knurled nut compression cap 40 has an opening through it of about the same cross-section and size as a light guide 44, and which is about the same cross-section as the opening in the shank 28.

The end of a conventional light guide 44, in the form of a cable or rod of an acrylic or other light guiding material, is installed through the open end of the cap 40. There is an open light pathway from the LED 14 through the housing 12, through the threaded shank 28 of the housing and into the light guide 44, and that pathway should be sealed against moisture, humidity, liquid and water.

An O-ring 46 seal inside the open distal end 48 of the cap 40 is squeezed by the turned in flange 49 at the distal end of the cap 40. The O-ring 46 forms a seal tightly to the light guide rod 44 and also provides a strong grip preventing separation of the light guide rod 44. The O-ring 46 at the knurled cap provides a water tight seal to the light guide, whereby moisture at the light guide will not pass through the knurled cap or into the light engine. With the O-ring seals 39 and 46, the LED 14 in the light engine housing and the light guide 44 are sealed against passage of moisture in both directions across the wall or panel 34. Further, the tight connection to the light guide prevents movement, shock or vibration to the light engine or the light guide from causing loosening of the light guide or its separation from the light engine or the wall or panel. It provides a superior continuous connection in the presence of shock and vibration environments, for example when used to illuminate a vehicle display.

In an alternate version, the barrel of the housing 12 is smaller, and there is no heat sink supporting the LEDs in the housing. Further, there may be only a single compression cap nut which has the dual purposes of holding the light rod securely and clamping the light engine to a wall or panel. There may be a fixed hexagonal shape grip below the threaded shank on the light engine and the wall or panel would be clamped between the knurled nut cap and fixed hexagonal grip. The two O-rings noted above both may be under the single knurled nut.

Larger light engine 10 can take light guide rods of 10-14 mm in diameter in the open end of the compression cap and the shank sometimes with inserts in the opening for adjusting for different diameter rods. A smaller light engine might handle light guides of 5-7 mm in diameter.

Several applications considered for the light engine include places where light is shown in moist environments and/or shaken or jolted environments, such as on boats, outdoors as in outdoor signs, advertising signs for illuminating machines in casinos, for illuminating objects like a modern day equivalent of a jukeboxes or music playing instruments, or wherever cable or rod light guides may be used, whether they are rigid or flexible guides.

Although the present invention has been described in relation to particular embodiments thereof, many other variations and modifications and other uses will become apparent to those skilled in the art. It is preferred, therefore, that the present invention be limited not by the specific disclosure herein, but only by the appended claims.

What is claimed is:

1. A light engine comprising:
a housing for containing at least one light emitting diode (LED), the housing having a distal end for being mounted at a panel and the distal end enabling illumination from the LED to pass out the distal end;
a shank projecting distally of the distal end of the housing, the shank being adapted for passing through an opening in the panel, from the proximal side of the panel at which the housing is to be disposed to the distal side of the panel;
the shank having an opening therein for receiving a light guide adapted for transmitting illumination from the LED into and along the light guide;
a first shank seal disposed around the shank at a location to engage the panel at the opening therethrough to seal passage through the panel past the shank;
the shank having a distal end, a cap secureable at the distal end of the shank with an opening shaped to permit the passage of the light guide through the cap and into the opening into the shank; and
a second light guide seal between the cap and the distal end of the shank and sealable against the light guide passed through the cap and in the shank.

2. The light engine of claim 1, further comprising a clamping element on the shank, at the distal side of the panel and at the first seal and being operable with respect to the shank for clamping on the first seal and effecting the sealing of the first seal at the distal side of the panel and the exterior of the shank.

3. The light engine of claim 1, wherein the shank is externally threaded and the end cap is internally threaded cooperatingly with the external thread on the shank for securing the cap on the shank by tightening the cap to the shank.

4. The light engine of claim 3, further comprising:
the clamping element for the first seal comprising a second nut that is internally threaded to cooperate with the external thread on the shank, so that the second nut is tightened toward the panel and holds the first seal.

5. The light engine of claim 1, wherein the first and the second seals are O-rings around the shank and around the light guide, respectively.

6. The light engine of claim 1, further comprising a circuit board in the housing and the LED is supported on the circuit board; and leads from the circuit board out of the housing.

7. The light engine of claim 6, further comprising a heat sink for the circuit board and the LEDs in the housing.

8. The light engine of claim 7, wherein the heat sink is in the housing.

9. The light engine of claim 1, further comprising a lens in the housing shaped and positioned to direct light onto the end of the light guide in the shank.

10. In combination, the light engine of claim 1 and a panel to which the light engine is attached, an opening in the panel through which the shank of a light engine passes, with the housing on a proximal side of the panel and the shank extending through an opening in the panel to a distal side of the panel;
the opening in the panel being sized so that a distally facing perimeter portion of the housing abuts the proximal side of panel outward of the opening thereof when the shank is secured by a securement at the distal side of the panel.
